(19) United States
(12) Patent Application Publication
(10) Pub. No.: US 2004/0037125 A1
(43) Pub. Date: Feb. 26, 2004

(54) Control device, control method and control program of disk drive enabling recovery from error state with high probability, and recording medium

(76) Inventor: Makoto Imagawa, Daito-shi (JP)

Correspondence Address: ROSENTHAL & OSHA L.L.P., 1221 MCKINNEY AVENUE, SUITE 2800, HOUSTON, TX, 77010, US

(21) Appl. No.: 10/641,601

(22) Filed: Aug. 15, 2003

(30) Foreign Application Priority Data
Aug. 20, 2002 (JP) 2002-239320(P)

(51) Int. Cl. G11C 29/00

(52) U.S. Cl. 365/200

(57) ABSTRACT

An address from which a disk drive is caused to start reading is set in step SA1, and reading is started in step SA2. Determination is made in step SA3 as to whether an error has occurred. In occurrence of an error, in step SA4, it is determined whether resetting of the read start address in step SA5 has been conducted a predetermined number of times or a predetermined time period has passed from the start of the read operation. If so, the read operation is terminated. If not, in step SA5, the address from which the disk drive is caused to start reading is reset to one sector ahead of the sector currently set. The process then returns to SA2, and the read operation is started from the reset address.

### BACKGROUND OF THE INVENTION

1. Field of the Invention

The present invention relates to a control device, a control method and a control program of a disk drive, and a recording medium. More particularly, the present invention relates to a control device, a control method and a control program of a disk drive improved in a recovery operation from an error state, and a recording medium.

2. Description of the Background Art

Conventionally, a disk drive has been incorporated in a system such as a personal computer or audio equipment, and operated as a front end in accordance with an instruction from a personal computer body or the like serving as a back end.

In control of the conventional disk drive, when an error occurs in a read operation of the disk drive, a retry instruction to repeat the read operation from the same position is given from the back end to the disk drive. If the disk drive cannot recover from the error state after the retry is performed a prescribed number of times, an instruction to stop the read operation of the disk is given to the disk drive.

It has conventionally been desired, when an error state occurs in the read operation of the disk drive, to make the disk drive recover from the error state and smoothly perform the read operation, rather than stopping the read operation.

### SUMMARY OF THE INVENTION

The present invention has been conceived in view of the foregoing, and an object of the present invention is to provide a control device, a control method and a control program of a disk drive which can make the disk drive recover from an error state during a read operation with higher probability, and a recording medium.

According to an aspect of the present invention, a control device of a disk drive reading information recorded on a disk causes the disk drive to start a read operation from a prescribed address on the disk. When an error occurs during the read operation of the disk drive from the prescribed address, the control device performs a special control to cause the disk drive to start the read operation from one sector ahead of the prescribed address. Further, if the error occurs during the read operation of the disk drive even after the special control is performed a predetermined number of times or for a predetermined time period, the control device causes the disk drive to stop the read operation.

According to the aspect of the present invention, a method of controlling a disk drive reading information recorded on a disk includes the step of causing the disk drive to start a read operation from a prescribed address on the disk, the step of performing a special control to cause the disk drive to start the read operation from one sector ahead of the prescribed address when an error occurs during the read operation of the disk drive from the prescribed address, and the step of causing the disk drive to stop the read operation when the error occurs during the read operation of the disk drive even after the special control is performed a predetermined number of times or for a predetermined time period.

A control program of a disk drive according to the aspect of the present invention is for controlling reading of information recorded on a disk by the disk drive. The control program causes a computer to perform the step of causing the disk drive to start a read operation from a prescribed address on the disk, the step of performing a special control to cause the disk drive to start the read operation from one sector ahead of the prescribed address when an error occurs during the read operation of the disk drive from the prescribed address, and the step of causing the disk drive to stop the read operation when the error occurs during the read operation of the disk drive even after the special control is performed a predetermined number of times or for a predetermined time period.

A recording medium according to the aspect of the present invention records the control program of a disk drive described above.

According to the aspect of the present invention, when an error occurs during a read operation from a prescribed address, the disk drive restarts the read operation from the preceding sector for a predetermined number of times or for a predetermined time period.

Thus, the disk device can recover from the error state with higher probability than in the case of retrying the read operation from the same sector. According to the present invention, particularly in a read operation of a CDDA (Compact Disk Digital Audio), recovery from an error state can be expected even in the case where information other than time information is recorded as subcode information on the CDDA and even if time information does not correspond to disk information other than the time information. The process of restarting the read operation from the preceding sector as described above is restricted to a predetermined number of times or a predetermined time period. Thus, the recovering operation is carried out efficiently.

According to another aspect of the present invention, a control device of a disk drive reading information recorded on a disk causes the disk drive to start a read operation from a prescribed address on a disk. When an error occurs during the read operation of the disk drive from the prescribed address, the control device causes the disk drive to start the read operation from one sector ahead of the prescribed address.

According to the another aspect of the present invention, a method of controlling a disk drive reading information recorded on a disk includes the step of causing the disk drive to start a read operation from a prescribed address on the disk, and the step of causing the disk drive to start the read operation from one sector ahead of the prescribed address when an error occurs during the read operation of the disk drive from the prescribed address.

A control program of a disk drive according to the another aspect of the present invention is for controlling reading of information recorded on a disk by the disk drive. The control program causes a computer to perform the step of causing the disk drive to start a read operation from a prescribed address on the disk, and the step of causing the disk drive to start the read operation from one sector ahead of the prescribed address when an error occurs during the read operation of the disk drive from the prescribed address.

A recording medium according to the another aspect of the present invention records the control program of a disk drive described above.

According to the another aspect of the present invention, when an error occurs during a read operation from a prescribed address, the disk drive restarts the read operation from the preceding sector.

Thus, the disk drive can recover from the error state with higher probability than in the case of retrying the reading from the same sector. According to the present invention, particularly in a read operation of a CDDA, recovery from an error state is expected even in the case where information other than time information is recorded as subcode information on the CDDA and even if time information and disk information other than the time information do not correspond to each other.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a control block diagram of a host computer as an embodiment of the present invention and a disk drive having its operation controlled by the host computer.

FIG. 2 is a flowchart illustrating a read start control process executed by a CPU (central processing unit) of the disk drive of FIG. 1.

### DESCRIPTION OF THE PREFERRED EMBODIMENTS

Hereinafter, a disk drive and a host computer controlling an operation of the disk drive are descried as an embodiment of the present invention.

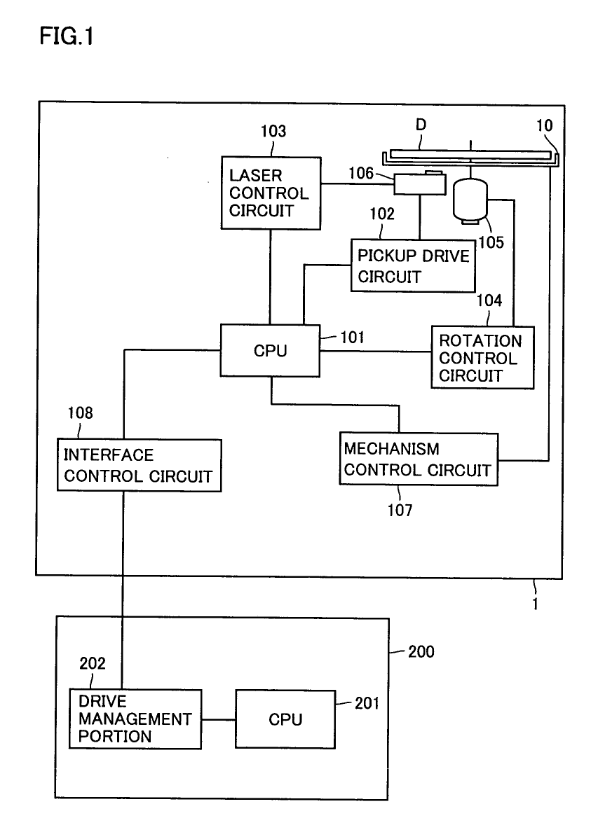

Referring to FIG. 1, a disk drive 1 includes a CPU 101, a pickup drive circuit 102, a laser control circuit 103, a rotation control circuit 104, a motor 105, a laser pickup 106, a mechanism control circuit 107, an interface circuit 108, and a disk tray 10 on which a disk D is mounted. Disk drive 1 is connected to a host computer 200 via interface circuit 108.

When disk D such as a CD (compact disc) is accommodated in disk drive 1, CPU 101 instructs rotation control circuit 104 to control the rotation of motor 105, so that a spin-up operation is started. CPU 101 instructs pickup drive circuit 102 to drive laser pickup 106 to read data from disk D. The data read from disk D is input to laser control circuit 103 for conversion into an electrical signal, which is then transmitted to host computer 200 via interface control circuit 108.

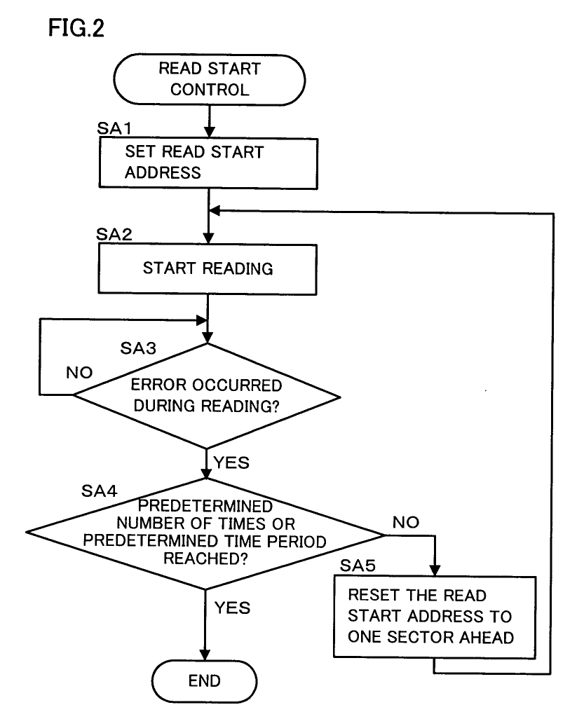

Host computer 200 includes a CPU 201 performing a control operation in the personal computer 200, and a drive management portion 202 controlling disk drive 1 based on a signal from CPU 201. CPU 201 transmits control information to disk drive 1 via drive management portion 202, to cause CPU 101 in disk drive 1 to perform an operation as shown, e.g., in FIG. 2.

Now, a process (read start control process) carried out by CPU 101 for causing disk drive 1 to start reading is explained with reference to FIG. 2. CPU 101 performs the read start control process when a disk is inserted into disk drive 1, or when disk drive 1 shifts from a stopped state to a reproducing state, in response to a prescribed operation performed on disk drive 1 or host computer 200. CPU 101 performs the read start control process in parallel with various kinds of processes such as a process of analyzing information read by disk drive 1.

In the read start control process, in step SA1 (hereinafter, “step” is not repeated), CPU 101 firstly receives an instruction from CPU 201 and sets an address from which disk drive 1 is to start reading.

Next, in SA2, CPU 101 causes disk drive 1 to start reading from the address set in SA1. In SA3, it determines whether an error has occurred in a read operation of disk drive 1.

When an error has occurred, in SA4, CPU 101 determines whether the address from which reading is started has been reset a prescribed number of times in SA5 described later, or whether a prescribed time period has passed from the start of the read operation. If so, CPU 101 causes disk drive 1 to terminate the read operation, and ends the process. If the prescribed number of times or the prescribed time period has not been reached, in SA5, CPU 101 resets the address from which disk drive 1 starts reading to one sector ahead of the currently-set sector. The process then returns to SA2, where CPU 101 causes disk drive 1 to start the read operation from the reset address.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A control device of a disk drive reading information recorded on a disk, comprising:
means for causing the disk drive to start a read operation from a prescribed address on said disk;
means for performing a special control to cause the disk drive to start the read operation from one sector ahead of the prescribed address when an error occurs during the read operation of said disk drive from the prescribed address; and
means for causing the disk drive to stop the read operation when the error occurs during the read operation of said disk drive even if said special control is carried out a predetermined number of times or for a predetermined time period.

2. A control device of a disk drive reading information recorded on a disk, comprising:
means for causing the disk drive to start a read operation from a prescribed address on said disk; and
means for causing the disk drive to start the read operation from one sector ahead of the prescribed address when an error occurs during the read operation of said disk drive from the prescribed address.

3. A method of controlling a disk drive reading information recorded on a disk, comprising the steps of:
causing the disk drive to start a read operation from a prescribed address on said disk;
performing a special control to cause the disk drive to start the read operation from one sector ahead of the prescribed address when an error occurs during the read operation of said disk drive from the prescribed address; and
causing the disk drive to stop the read operation when the error occurs during the read operation of said disk drive even if said special control is carried out a predetermined number of times or for a predetermined time period.

4. A method of controlling a disk drive reading information recorded on a disk, comprising the steps of:
causing the disk drive to start a read operation from a prescribed address on said disk, and
causing the disk drive to start the read operation from one sector ahead of the prescribed address when an error occurs during the read operation of said disk drive from the prescribed address.

5. A program for controlling reading of information recorded on a disk by a disk drive, causing a computer to perform the steps of:
causing the disk drive to start a read operation from a prescribed address on said disk, performing a special control to cause the disk drive to start the read operation from one sector ahead of the prescribed address when an error occurs during the read operation of said disk drive from the prescribed address, and
causing the disk drive to stop the read operation when the error occurs during the read operation of said disk drive even if said special control is carried out a predetermined number of times or for a predetermined time period.

6. A program for controlling reading of information recorded on a disk by a disk drive, causing a computer to perform the steps of:
causing the disk drive to start a read operation from a prescribed address on said disk, and
causing the disk drive to start the read operation from one sector ahead of the prescribed address when an error occurs during the read operation of said disk drive from the prescribed address.

7. A recording medium recording the control program of a disk drive according to claim 5.

8. A recording medium recording the control program of a disk drive according to claim 6.
